(19) United States
(12) Patent Application Publication
(10) Pub. No.: US 2025/0022862 A1
(43) Pub. Date: Jan. 16, 2025

(54) DISPLAY DEVICE AND METHOD OF FABRICATING THE SAME

(71) Applicant: Samsung Display Co., LTD., Yongin-si (KR)

(72) Inventors: Kyung Rock SON, Yongin-si (KR); Hui Won YANG, Yongin-si (KR)

(21) Appl. No.: 18/588,306

(22) Filed: Feb. 27, 2024

(30) Foreign Application Priority Data
Jul. 14, 2023 (KR) 10-2023-0091875

(51) Int. Cl. H01L 25/16; H01L 25/075; H01L 33/40; H01L 33/62

(52) U.S. Cl. CPC H01L 25/167; H01L 25/0753; H01L 33/405; H01L 33/62; H01L 2933/0016; H01L 2933/0066

(57) ABSTRACT

A method of fabricating a display device includes forming a transistor above a substrate, and a pixel electrode at a same layer as one of electrodes of the transistor, forming an adhesive layer on the pixel electrode, placing a light-emitting element on the adhesive layer, forming an insulting layer to cover the transistor, the pixel electrode, and the light-emitting element, and forming a first bridge pattern electrically connecting the transistor to a first end of the light-emitting element, and a second bridge pattern electrically connected to a second end of the light-emitting element, wherein the light-emitting element is primarily fixed by the adhesive layer, and wherein the light-emitting element is secondarily fixed by the insulating layer.

### CROSS-REFERENCE TO RELATED APPLICATION

The present application claims priority to, and the benefit of, Korean Patent Application No. 10-2023-0091875, filed on Jul. 14, 2023, in the Korean Intellectual Property Office, the entire disclosure of which is incorporated herein by reference.

### BACKGROUND

### 1. Field

Various embodiments of the present disclosure relate to a display device, and to a method of fabricating the display device.

### 2. Description of Related Art

With an increase in interest in an information display, and with an increase in demand to use portable information media, demand for display devices is markedly increased, and commercialization thereof is in progress.

### SUMMARY

Various embodiments of the present disclosure are directed to a display device, and to a method of fabricating the display device with improved yield.

The aspects of the present disclosure are not limited to the above, and those skilled in the art will clearly understand other unmentioned aspects from the accompanying claims.

One or more embodiments of the present disclosure may provide a method of fabricating a display device, the method including forming a transistor above a substrate, and a pixel electrode at a same layer as one of electrodes of the transistor, forming an adhesive layer on the pixel electrode, placing a light-emitting element on the adhesive layer, forming an insulting layer to cover the transistor, the pixel electrode, and the light-emitting element, and forming a first bridge pattern electrically connecting the transistor to a first end of the light-emitting element, and a second bridge pattern electrically connected to a second end of the light-emitting element, wherein the light-emitting element is primarily fixed by the adhesive layer, and wherein the light-emitting element is secondarily fixed by the insulating layer.

The light-emitting element may include a first semiconductor layer, an emission layer, and a second semiconductor layer that are sequentially stacked from the second end to the first end, wherein an outer circumferential surface of each of the first semiconductor layer, the emission layer, and the second semiconductor layer is covered with the insulating layer.

The insulating layer may include inorganic material.

The first end of the light-emitting element may contact the adhesive layer, wherein the first bridge pattern contacts the pixel electrode, and wherein the first end of the light-emitting element is electrically connected to the pixel electrode by the adhesive layer.

The adhesive layer may include silver paste, wherein forming the adhesive layer includes heat-curing the silver paste, and wherein the light-emitting element is fixed to the pixel electrode by the cured silver paste.

The pixel electrode may include reflective metal.

The method may further include forming an organic layer and an inorganic layer on the insulating layer, wherein a portion of the insulating layer in contact with the second end of the light-emitting element is exposed from the organic layer and the inorganic layer.

The transistor may include a gate electrode above a semiconductor pattern, and a back gate electrode beneath the semiconductor pattern and overlapping the gate electrode, wherein the pixel electrode is at a same layer as the back gate electrode.

The transistor may include a gate electrode above a semiconductor pattern, wherein the pixel electrode is at a same layer as the gate electrode.

The adhesive layer may include photoresist, wherein the pixel electrode is electrically separated from a bottom surface of the light-emitting element and the transistor.

One or more embodiments of the present disclosure may provide a display device including a transistor above a substrate, a pixel electrode at a same layer as one of electrodes of the transistor, an adhesive layer above the pixel electrode, a light-emitting element above the adhesive layer, and including a first semiconductor layer, an emission layer, and a second semiconductor layer that are sequentially stacked from a second end to a first end, an insulting layer covering the transistor, the pixel electrode, and the light-emitting element, and covering an outer circumferential surface of the first semiconductor layer, the emission layer, and the second semiconductor layer, a first bridge pattern above the insulating layer, and electrically connecting the transistor to the first end of the light-emitting element, and a second bridge pattern above the insulating layer, and electrically connected to the second end of the light-emitting element.

The first bridge pattern may contact the pixel electrode, wherein the first end of the light-emitting element contacts the adhesive layer to be electrically connected to the pixel electrode.

The adhesive layer may include silver paste, wherein the light-emitting element is fixed to the pixel electrode by the silver paste being cured.

The pixel electrode may include reflective metal.

The display device may further include an organic layer and an inorganic layer sequentially on the insulating layer, wherein a portion of the insulating layer in contact with the second end of the light-emitting element is exposed from the organic layer and the inorganic layer.

The transistor may include a gate electrode above a semiconductor pattern, and a back gate electrode beneath the semiconductor pattern and overlapping the gate electrode, wherein the pixel electrode is at a same layer as the back gate electrode.

The transistor may include a gate electrode above a semiconductor pattern, wherein the pixel electrode is at a same layer as the back gate electrode.

The adhesive layer may include photoresist.

The pixel electrode may be electrically separated from a bottom surface of the light-emitting element.

The light-emitting element may include a flip-chip-type micro light-emitting diode.

Details of various embodiments are included in the detailed descriptions and drawings.

### BRIEF DESCRIPTION OF THE DRAWINGS

FIG. 1 is a plan view illustrating a display device in accordance with one or more embodiments.

FIG. 2 is a circuit diagram illustrating one or more embodiments of a pixel included in the display device of FIG. 1.

FIG. 3 is a sectional view illustrating one or more embodiments of the display device of FIG. 1.

FIGS. 4 to 9 are sectional views illustrating a method of fabricating the display device of FIG. 3.

FIG. 10 is a sectional view illustrating one or more embodiments of the display device of FIG. 1.

FIG. 11 is a sectional view illustrating one or more embodiments of the display device of FIG. 1.

FIGS. 12 to 16 are sectional views illustrating a method of fabricating the display device of FIG. 11.

FIG. 17 is a sectional view illustrating one or more embodiments of the display device of FIG. 1.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” and “at least one of A or B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, a display device in accordance with one or more embodiments of the present disclosure will be described with reference to the attached drawings.

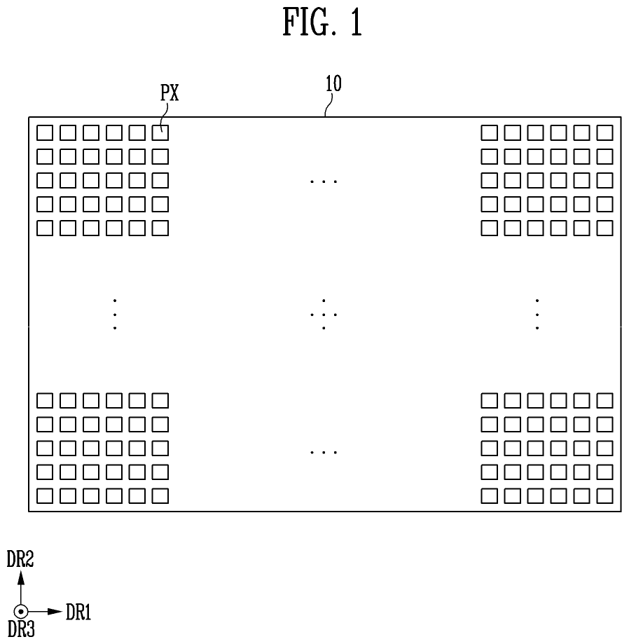

FIG. 1 is a plan view illustrating a display device in accordance with one or more embodiments.

Referring to FIG. 1, the display device 10 (or a display panel) may be a device configured to display an image, and may be used not only as portable electronic devices, such as a mobile phone, a smart phone, a tablet personal computer (a table PC), a smart watch, a watch phone, a mobile communication terminal, an electronic notebook, an electronic book, a portable multimedia player (PMP), a navigation device, and an ultra-mobile PC (UMPC), but also as display screens of various products, such as a television, a notebook, a monitor, an advertisement panel, and an internet of tings (IOT).

The display device 10 may be formed of a rectangular panel having long sides extending in a first direction DR1, and short sides extending a second direction DR2 crossing the first direction DR1. Respective corners where the long sides extending in the first direction DR1 and the short sides extending in the second direction DR2 meet may be rounded with a corresponding curvature, or may be formed at a substantially right angle. The plane shape of the display device 10 is not limited to a rectangular shape, and may have other polygonal shapes, a circular shape, or an elliptical shape. The display device 10 (or a planar shape of the display device 10) may have an irregular shape (or may be irregular). The display device 10 may be formed to be planar, but is not limited thereto. For example, the display device 10 may include a curved surface that is formed on each of left and right side edges thereof, and that has a constant curvature or a varying curvature. In addition, the display device 10 may be formed to be flexible so that the display device 10 can be bent, curved, folded, or rolled.

The display device 10 may include pixels PX (or sub-pixels) to display an image. The pixels PX may be arranged in the form of a matrix in the first direction DR1 and the second direction DR2, but the present disclosure is not limited thereto. The display device 10 may further include gate lines (or scan lines) extending in the first direction DR1, and data lines extending in the second direction DR2.

Each pixel PX may include an inorganic light-emitting element having an inorganic semiconductor as a light-emitting element for emitting light. For example, the inorganic light-emitting element may be a flip-chip-type micro light-emitting diode (LED), but embodiments of the present disclosure are not limited thereto.

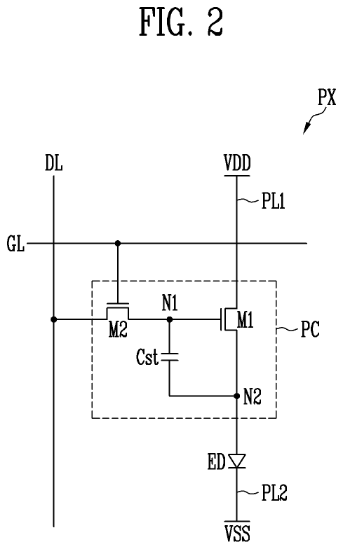

FIG. 2 is a circuit diagram illustrating one or more embodiments of a pixel PX included in the display device of FIG. 1.

Referring to FIG. 2, the pixel PX may be connected to a gate line GL, a data line DL, a first power line PL1, and a second power line PL2. Furthermore, the pixel PX may be further connected to at least one power line and/or signal line.

A gate signal (or a scan signal) may be supplied to the gate line GL. A data signal may be supplied to the data line DL. A voltage of a first power supply VDD may be applied to the first power line PL1. A voltage of a second power supply VSS may be applied to the second power line PL2. The first power supply VDD and the second power supply VSS may have different potentials.

The pixel PXL may include a light-emitting element ED configured to generate light with a luminance corresponding to a data signal. Furthermore, the pixel PX may further include a pixel circuit PC configured to drive the light-emitting element ED.

The pixel circuit PC may be electrically connected to the gate line GL and the data line DL, and may be electrically connected between the first power line PL1 and the light-emitting element ED.

The pixel circuit PC may include at least one transistor and at least one capacitor Cst. For example, the pixel circuit PC may include a first transistor M1, a second transistor M2, and a capacitor Cst.

The first transistor M1 may be connected between the first power line PL1 and a second node N2. The second node N2 may be a node to which the pixel circuit PC and the light-emitting element ED are connected. For example, the second node N2 may be a node by which one electrode (e.g., a source electrode) of the first transistor M1 is electrically connected to the light-emitting element ED. A gate electrode of the first transistor M1 may be connected to a first node N1. The first transistor M1 may control driving current to be supplied to the light-emitting element ED in response to a voltage of the first node N1. For example, the first transistor M1 may be a driving transistor of the pixel PX.

The second transistor M2 may be connected between the data line DL and the first node N1. A gate electrode of the second transistor M2 may be connected to the gate line GL. When a gate signal of a gate-on voltage (e.g., a logic high voltage or a high-level voltage) is supplied from the gate line GL, the second transistor M2 may be turned on to connect the data line DL with the first node N1.

During each frame period, a data signal of the corresponding frame may be supplied to the data line DL, and the data signal may be transmitted to the first node N1 through the second transistor M2 during a period during which the gate signal of a gate-on voltage is supplied. For example, the second transistor M2 may be a switching transistor configured to transmit each data signal to the interior of the pixel PX.

A first electrode of the capacitor Cst may be connected to the first node N1. A second electrode of the capacitor Cst may be connected to the second node N2. The capacitor Cst may be charged with a voltage corresponding to a data signal to be supplied to the first node N1 during each frame period.

Although in FIG. 2 both the first and second transistors M1 and M2 included in the pixel circuit PC are described as n-type transistors, the embodiments are not limited thereto. For example, at least one of the first or second transistors M1 or M2 may be a p-type transistor. The structure and driving method of the pixel PXL may be changed in various ways depending on the embodiments.

Furthermore, the pixel circuit PC may further include other circuit elements, such as an initialization transistor (or a sensing transistor) configured to initialize an anode electrode of the light-emitting element ED, a compensation transistor configured to compensate for a threshold voltage of the first transistor M1, an initialization transistor configured to initialize a voltage of the first node N1, an emission control transistor configured to control a period during which driving current is supplied to the light-emitting element ED, and/or a boosting capacitor configured to boost the voltage of the first node N1.

The light-emitting element ED may emit light with a luminance corresponding to driving current supplied thereto through the pixel circuit PC. The light-emitting element ED may be connected between the first transistor M1 and the second power line PL2. A first electrode of the light-emitting element ED may be connected to one electrode of the first transistor M1 (or the second node N2). A second electrode of the light-emitting element ED may be connected to the second power line PL2. Here, the first electrode of the light-emitting element ED may be an anode electrode, and the second electrode of the light-emitting element ED may be a cathode electrode. The light-emitting element ED may be an inorganic light-emitting element including a first electrode, a second electrode, and an inorganic semiconductor located between the first electrode and the second electrode. For example, the light-emitting element ED may be a micro LED formed of an inorganic semiconductor, but it not limited thereto.

Although the pixel PX has been illustrated in FIG. 2 as including only one light-emitting element ED, the embodiments of the present disclosure are not limited thereto. For example, the pixel PX may further include at least one light-emitting element connected in parallel to the light-emitting element ED. As another example, the pixel PX may further include at least one light-emitting element connected in series to the light-emitting element ED. The number, type, and/or structure of light-emitting elements ED that form a valid light source of the pixel PX may be changed depending on the embodiments.

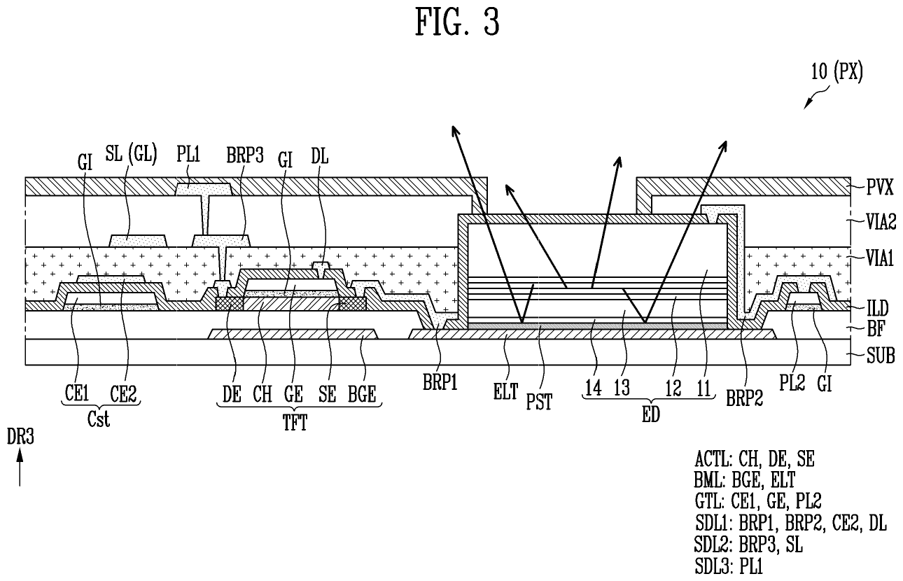

FIG. 3 is a sectional view illustrating one or more embodiments of the display device 10 of FIG. 1. In FIG. 3, there is illustrated a sectional view of the display device 10 based on one pixel PX (or a pixel area).

Referring to FIGS. 1 to 3, the pixel PX (or the display device 10) may include a substrate SUB, a buffer layer BF, a bottom electrode layer BML, an active layer ACTL (or an active pattern), a gate-insulating layer GI, a gate layer GTL, an interlayer insulating layer ILD, a first source metal layer SDL1, a first via layer VIA1 (or a first organic layer), a second source metal layer SDL2, a second via layer VIA2 (or a second organic layer), a third source metal layer SDL3, and a passivation layer PVX (or an inorganic layer).

In one or more embodiments of the present disclosure, unless otherwise explained, “components are provided and/or formed in the same layer” may mean that the components are formed through the same process, and “components are provided and/or formed in different layers” may mean that the components are formed through different processes.

The substrate SUB (or a base layer) may be a base substrate or a base component for supporting the display device 10. The substrate SUB may be a rigid substrate made of glass. Alternatively, the substrate SUB may be a flexible substrate that is bendable, foldable, rollable, or the like. In this case, the substrate SUB may include insulating material, such as polymer resin, e.g., polyimide (PI).

The substrate SUB may include an emission area and a non-emission area, based on a single pixel PX. In a plan view, in the emission area, there is provided the light-emitting element ED, and in the non-emission area, there are located a thin-film transistor TFT (or a transistor), a signal line (e.g., the data line DL) and the power lines PL1 and PL2. The thin-film transistor TFT, the signal line, and the power lines are not located in the emission area.

The bottom electrode layer BML may be located on the substrate SUB. The

bottom electrode layer BML may include a bottom gate electrode BGE (or a back gate electrode, or a bottom electrode). The bottom gate electrode BGE may overlap the active layer ACTL (or a channel CH of the thin-film transistor TFT) in a third direction DR3. The bottom gate electrode BGE may block light irradiated onto the active layer ACTL in the third direction DR3, thus mitigating or improving changes in characteristics of the thin-film transistor TFT otherwise resulting from exposure to light.

In one or more embodiments, the bottom electrode layer BML may further include a pixel electrode ELT. The pixel electrode ELT may be an anode electrode. The pixel electrode ELT may be located in the same layer as one of the electrodes of the thin-film transistor TFT. In one or more embodiments, the pixel electrode ELT may be located in the same layer as the bottom gate electrode BGE of the thin-film transistor TFT.

The bottom electrode layer BML may include conductive material. For example, the conductive material may include copper (Cu), molybdenum (Mo), tungsten (W), neodymium (Nd), titanium (Ti), aluminum (Al), silver (Ag), chromium (Cr), gold (Au), silver (Ag), and/or an alloy thereof, and may be formed as a single layer or as multiple layers.

In one or more embodiments, the bottom electrode layer BML may include conductive material with a high reflectance. For example, the bottom electrode layer BML may include metal, such as silver (Ag), copper (Cu), or aluminum (Al), or may include an alloy including aluminum (Al), nickel (Ni), lanthanum (La), or the like. However, the present disclosure is not limited thereto, and the bottom electrode layer BML may further include transparent conductive material. For example, the bottom electrode layer BML may include materials, such as indium tin oxide (ITO), indium zinc oxide (IZO), and/or indium tin-zinc oxide (ITZO). In one or more embodiments, the bottom electrode layer BML may be provided as a structure formed by stacking one or more transparent conductive material layers and one or more metal layers with a high reflectance on top of each other, or may be formed as a single layer including a transparent conductive material layer and a metal layer. For example, the bottom electrode layer BML may include metal materials, such as a stacked structure (Ti/AI/Ti) of aluminum and titanium, a stacked structure (ITO/AI/ITO) of aluminum and ITO, an APC alloy, or a stacked structure (ITO/APC/ITO) of an APC alloy and ITO. The APC alloy may be an alloy of silver (Ag), palladium (Pd), and copper (Cu).

The buffer layer BF (or a buffer film) may be located on the substrate SUB. The buffer layer BF may reduce or prevent permeation of air or water. The buffer layer BF may be an inorganic insulating layer including inorganic material. For example, the inorganic material may include at least one of silicon nitride (SiNx), silicon oxide (SiOx), silicon oxynitride (SiOxNy), or metal oxide, such as aluminum oxide (AlOx).

The buffer layer BF may cover the bottom electrode layer BML except for at least a portion of the pixel electrode ELT. The buffer layer BF may include, or define, an opening through which the pixel electrode ELT is exposed.

An adhesive layer PST (or a temporary adhesive layer) may be located on the pixel electrode ELT. The adhesive layer PST may fix or couple the light-emitting element ED to the pixel electrode ELT.

In one or more embodiments, the adhesive layer PST may include silver paste. For example, the silver paste may include silver nanoparticles mixed in resin, such as acrylic resin or epoxy resin. The adhesive layer PST including silver paste may electrically connect the light-emitting element ED to the pixel electrode ELT. However, the adhesive layer PST is not limited to the aforementioned embodiments. For example, the adhesive layer PST may include conductive particles, such as copper, and nickel, in addition to silver. As another example, the adhesive layer PST may not include conductive particles, and may include insulating material, such as photoresist.

For reference, to bond the light-emitting element ED to the pixel electrode ELT, a method, such as an anisotropic conductive film (ACF)-bonding method using an ACF or a eutectic bonding method may be used. However, in the case of the ACF-bonding method, if applying pressure to the light-emitting element ED (and the ACF) to bond the light-emitting element ED to the pixel electrode ELT, conductive balls in the ACF may be displaced outwardly from an area between the light-emitting element ED and the pixel electrode ELT, thus potentially resulting in improper connection between the light-emitting element ED and the pixel electrode ELT.

The eutectic bonding method is a relatively low-temperature bonding technique that involves applying pressure and heat to a metal thin-film (e.g., copper, tin, gold, lead, or the like) with a relatively low melting point (ranging from about 200° C. to about 500° C.). However, even though it is considered a low-temperature process, a process temperature of at least about 180° C. is suitable. Depending on the materials and processes of the components in the display device 10, the eutectic bonding method, which suitably uses a process temperature of about 180° C., may not be applicable. Furthermore, taking into account adhesive strength between the pixel electrode ELT and the light-emitting element ED, the types of metal films may be limited.

Silver paste, when cured, may have adhesive properties, and curing conditions for silver paste may be about 12 hours at about 25° C. or about 30 minutes at about 100° C. In other words, the light-emitting element ED may be bonded to the pixel electrode ELT at lower process temperatures. The adhesive strength of the silver paste (e.g., ranging from about 70 kgf/cm² to about 80 kgf/cm²) alone may not be sufficient for the light-emitting element ED to withstand a cleaning process (e.g., at pressure of about 120 kgf/cm²) or the like. Given this, the light-emitting element ED may be reliably fixed by covering the light-emitting element ED with an interlayer insulating layer ILD to be described below. The adhesive strength of the silver paste may be sufficient to maintain the fixed state of the light-emitting element ED during a deposition process of the interlayer insulating layer ILD. In other words, the light-emitting element ED may be temporarily fixed or bonded by the silver past and, thereafter, the light-emitting element ED may be reliably fixed by the interlayer insulating layer ILD.

The light-emitting element ED may include a first semiconductor layer 11, an emission layer 12 (or an active layer), a second semiconductor layer 13, and an element electrode layer 14. The first semiconductor layer 11 may be a second end of the light-emitting element ED, and the element electrode layer 14 may be a first end of the light-emitting element ED. The first semiconductor layer 11, the emission layer 12, the second semiconductor layer 13, and the element electrode layer 14 may be sequentially stacked from the second end to the first end in one direction.

The first semiconductor layer 11 may be doped with a first conductive dopant. The first conductive type may refer to an n-type. The first conductive dopant may include Si, Ge, Sn, and so on. In other words, the first semiconductor layer 11 may include an n-type semiconductor. For example, the first semiconductor layer 11 may include n-GaN doped with n-type Si.

The second semiconductor layer 13 may be located at a position spaced apart from the first semiconductor layer 11 with the emission layer 12 interposed therebetween. The second semiconductor layer 13 may be doped with a second conductive dopant. The second conductive type may refer to a p-type. The second conductive dopant may include Mg, Zn, Ca, Sr, Ba, and so on. In other words, the second semiconductor layer 13 may include a p-type semiconductor. For example, the second semiconductor layer 13 may include p-GaN doped with p-type Mg.

Although each of the first semiconductor layer 11 and the second semiconductor layer 13 is formed as a single layer, the embodiments of the present disclosure are not limited thereto. For example, depending on the material included in the emission layer 12, at least one of the first semiconductor layer 11 or the second semiconductor layer 13 may include a greater number of layers, such as a clad layer or a tensile strain barrier reducing (TSBR) layer.

The emission layer 12 may be located between the first semiconductor layer 11 and the second semiconductor layer 13. The emission layer 12 may include material having a single or multiple quantum well structure. The emission layer 12 may emit light by combination of electron-hole pairs in response to electric signals applied through the first semiconductor layer 11 and the second semiconductor layer 13. For example, in case that the emission layer 12 emits light in a blue wavelength band, the emission layer 12 may include material, such as AlGaN or AlGaInN, but the embodiments of the present disclosure are not limited thereto.

In embodiments, the emission layer 12 may have a structure formed by alternately stacking semiconductor materials having large band gap energy and semiconductor materials having small band gap energy, and may include Group-III to Group-V semiconductor materials depending on the wavelength band of light to be emitted. Light emitted from the emission layer 12 is not limited to light in a blue wavelength band, and may be light in a red or green wavelength band in some cases.

Light emitted from the emission layer 12 may be emitted through a side surface of the light-emitting element ED in addition to the opposite ends of the light-emitting element ED. A light output direction of light emitted from the emission layer 12 is not limited to a specific direction.

The opposite ends of the light-emitting element ED are electrically connected to external electrodes (e.g., the pixel electrodes ELT) to apply electrical signals to the first semiconductor layer 11 and the second semiconductor layer 13. The element electrode layer 14 may be located between the second semiconductor layer 13 and the corresponding external electrode (e.g., the corresponding pixel electrode ELT), thus reducing resistance. The element electrode layer 14 may include at least one of aluminum (Al), titanium (Ti), indium (In), gold (Au), silver (Ag), indium tin oxide (ITO), indium zinc oxide (IZO), or ITZO (indium tin zinc oxide). In one or more embodiments, the element electrode layer 14 may include a semiconductor material doped with either n-type or p-type dopant.

The element electrode layer 14 may be located under the second semiconductor layer 13, but the embodiments of the present disclosure are not limited thereto. For example, a separate element electrode layer may be further located on the first semiconductor layer 11.

The element electrode layer 14 (or the first end) of the light-emitting element ED may contact the adhesive layer PST, and may be electrically connected to the pixel electrode ELT by the adhesive layer PST.

The active layer ACTL may be located on the buffer layer BF. The active layer ACTL may include a silicon semiconductor, such as a poly-crystal silicon semiconductor, a single-crystal silicon semiconductor, a low temperature poly-crystal silicon semiconductor, and an amorphous silicon semiconductor, or may include an oxide semiconductor.

The active layer ACTL may include a channel CH, a first electrode SE, and a second electrode DE of the thin-film transistor TFT. Here, the thin-film transistor TFT is a transistor included in the pixel circuit PC of FIG. 2. For example, the thin-film transistor TFT may correspond to the first transistor M1. The channel CH of the transistor TFT may refer to an area overlapping the gate electrode GE of the thin-film transistor TFT in the third direction DR3. The first electrode SE of the thin-film transistor TFT may be located on one side of the channel CH, and the second electrode DE may be located on another side of the channel CH. The first electrode SE and the second electrode DE of the thin-film transistor TFT may refer to an area that does not overlap the gate electrode GE in the third direction DR3. The channel CH of the thin-film transistor TFT may be an intrinsic semiconductor as an undoped semiconductor pattern. The first electrode SE and the second electrode DE of the thin-film transistor TFT may be semiconductor patterns doped with impurities.

The gate-insulating layer GI may be located on the active layer ACTL and the buffer layer BF. The gate-insulating layer GI may be an insulating layer including inorganic material.

A gate electrode GTL may be located on the gate-insulating layer GI. The gate layer GTL may include conductive material, and may be formed as a single layer or multiple layers. The gate layer GTL may include the gate electrode GE of the thin-film transistor TFT, a first capacitor electrode CE1, and the second power line PL2.

The interlayer insulating layer ILD (or an insulating layer) may be located on the gate layer GTL. The interlayer insulating layer ILD may be an insulating layer including inorganic material. The interlayer insulating layer ILD may be formed as a single layer or multiple layers. The interlayer insulating layer ILD may cover the thin-film transistor TFT, the pixel electrode ELT, and the light-emitting element ED.

In one or more embodiments, the interlayer insulating layer ILD may directly cover an outer circumferential surface (or a side surface) of the light-emitting element ED. The interlayer insulating layer ILD may reduce or prevent the likelihood of short circuits between the light-emitting element ED and adjacent components. Furthermore, the insulating layer INF may reduce or minimize surface defects of the light-emitting element LD, thus enhancing the efficiency and life span of the light-emitting element LD. The surface defects may occur on the surface of the semiconductor layer exposed to etchant at the outermost edge during an etching process in a process of fabricating the light-emitting element ED. The surface defects may induce leakage of electrons injected into the semiconductor layer, or may induce trapping of holes, thereby impeding the combination between the electrons and holes, and thus reducing the light efficiency of the light-emitting element ED. In the case where the interlayer insulating layer ILD is directly located or formed on the side surface of the light-emitting element ED, the side surface of the light-emitting element ED may have the effect of surface treatment.

For reference, in the case where the light-emitting element ED is fabricated separately from the display device 10, an insulating layer (or a passivation layer) is formed on the outer circumferential surface of the light-emitting element ED during the process of fabricating the light-emitting element ED to reduce or minimize the surface defects. In the present disclosure, the interlayer insulating layer ILD functions as an insulating layer for the light-emitting element ED, there is no need to form a separate insulating layer on the light-emitting element ED during the process of fabricating the light-emitting element ED. Therefore, the production cost of the light-emitting element ED and the display device 10 including the light-emitting element ED may be reduced.

The first source metal layer SDL1 may be located on the interlayer insulating layer ILD. The first source metal layer SDL1 may include conductive material, and may be formed as a single layer or multiple layers.

The first source metal layer SDL1 may include a first bridge pattern BRP1, a second bridge pattern BRP2, a second capacitor electrode CE2, and a data line DL. The first bridge pattern BRP1 may be brought into contact with, or may be connected to, the first electrode SE (or the second electrode DE) of the thin-film transistor TFT through a contact hole passing through the interlayer insulating layer ILD. Furthermore, the first bridge pattern BRP1 may be brought into contact with, or may be connected to, the pixel electrode ELT through a contact hole passing through the interlayer insulating layer ILD.

The second bridge pattern BRP2 may be connected to the first semiconductor layer 11 of the light-emitting element ED through a contact hole passing through the interlayer insulating layer ILD. Furthermore, the second bridge pattern BRP2 may be connected to the second power line PL2 through a contact hole passing through the interlayer insulating layer ILD.

The second capacitor electrode CE2, along with the first capacitor electrode CE1, may form the capacitor Cst (refer to FIG. 2). The data line DL may be the data line DL described with reference to FIG. 2.

The first via layer VIA1 (referred also to as a first planarization layer) may be located on the first source metal layer SDL1. The first via layer VIA1 may planarize a stepped surface caused by the bottom electrode layer BML, the active layer ACTL, the gate layer GTL, and/or the first source metal layer SDL1. The first via layer VIA1 may be an insulating layer including organic material. For example, the organic material may include acryl resin, epoxy resin, phenolic resin, polyamide resin, polyimide resin, or the like. In one or more embodiments, the first via layer VIA1 may not cover the light-emitting element ED (or an area corresponding to the light-emitting element ED). The second source metal layer SDL2 may be located on the first via layer VIA1. The second source metal layer SDL2 may include conductive material, and may be formed as a single layer or multiple layers.

The second source metal layer SDL2 may include a third bridge pattern BRP3 and a signal line SL. The third bridge pattern BRP3 may be connected to the second electrode DE of the thin-film transistor TFT through a contact hole passing through the first via layer VIA1. The signal line SL may be the gate line GL described with referent to FIG. 2, or may include the gate line GL.

The second via layer VIA2 (referred also to as a second planarization layer) may be located on the second source metal layer SDL2. The second via layer VIA2 may be an insulating layer including organic material. In one or more embodiments, the second via layer VIA2 may not cover at least a portion of the light-emitting element ED (or an area corresponding to the light-emitting element ED). In other words, the second via layer VIA2 may include, or define, an opening corresponding to the light-emitting element ED.

The third source metal layer SDL3 may be located on the second via layer VIA2. The third source metal layer SDL3 may include conductive material, and may be formed as a single layer or multiple layers.

The third source metal layer SDL3 may include the first power line PL1. The first power line PL1 may be brought into contact with, or may be connected to, the third bride pattern BRP3 through a contact hole passing through the second via layer VIA2. The first power line PL1 may be connected to the second electrode DE of the thin-film transistor TFT through the third bridge pattern BRP3.

The passivation layer PVX may be located on the third source metal layer SDL3. The passivation layer PVX may be an insulating layer including inorganic material. In one or more embodiments, the passivation layer PVX may not cover the light-emitting element ED (or an area corresponding to the light-emitting element ED).

In the case where a plurality insulating layers are present on the light-emitting element ED, reflection of light between the insulating layers may lead to a reduction in the light output efficiency of the display device 10. Therefore, taking into account the light output efficiency, the second via layer VIA2 and the passivation layer PVX may not cover the light-emitting element ED (or an area corresponding to the light-emitting element ED). However, the present disclosure is not limited to the aforementioned examples, the second via layer VIA2 and the passivation layer PVX may cover the light-emitting element ED (or an area corresponding to the light-emitting element ED).

In one or more embodiments, a light conversion pattern may be located or provided in the opening of the second via layer VIA2 (or on the light-emitting element ED). For example, the light conversion pattern may use color conversion particles (or quantum dots) to change or convert the wavelength (or the color) of light emitted from the light-emitting element ED.

As described above, the pixel electrode ELT may be located on the same layer as the bottom gate electrode BGE that is one electrode of the thin-film transistor TFT. The light-emitting element ED may be temporarily fixed (or primarily fixed) or coupled to the pixel electrode ELT through the adhesive layer PST. The interlayer insulating layer ILD may directly cover the light-emitting element ED, thus completely (or secondarily) fixing the light-emitting element ED in place. Because the light-emitting element ED is fixed in place by the adhesive layer PST and the interlayer insulating layer ILD, the light-emitting element ED may be fixed or coupled to the pixel electrode ELT by only a low-temperature process without the need for a high-temperature process and/or a press process. Therefore, damage to components in the display device 10 due to high-temperature processes can be reduced or prevented from occurring, whereby the yield of the display device 10 may be improved.

Furthermore, the interlayer insulating layer ILD directly covers the outer circumferential surface (or the side surface) of the light-emitting element ED, thus reducing or minimizing surface defects of the light-emitting element ED. Consequently, there is no need to form a separate insulating layer (e.g., an insulating layer designed to reduce or minimize surface defects) on the light-emitting element ED during the process of fabricating the light-emitting element ED. Therefore, the production cost of the light-emitting element ED and the display device 10 including the light-emitting element ED may be reduced.

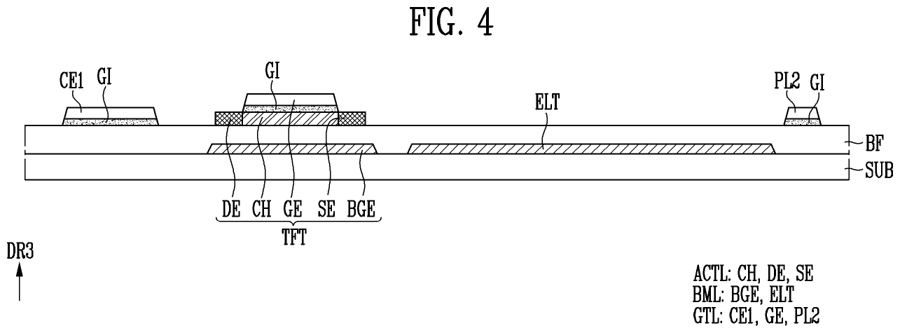

FIGS. 4 to 9 are sectional views illustrating a method of fabricating the display device of FIG. 3.

Referring to FIGS. 3 to 9, the thin-film transistor TFT and the pixel electrode ELT may be formed on the substrate SUB.

As illustrated in FIG. 4, the bottom electrode layer BML, which includes the bottom gate electrode BGE and the pixel electrode ELT, may be formed on the substrate SUB. The bottom electrode layer BML or the pixel electrode ELT may include conductive materials, such as silver (Ag), copper (Cu), and/or aluminum (Al), having high reflectance. The buffer layer BF may be formed to cover the bottom electrode layer BML. The active layer ACTL may be located on the buffer layer BF to overlap the bottom gate electrode BGE. The gate-insulating layer GI may be located on the active layer ACTL. The gate layer GTL may be located on the gate-insulating layer GI. For example, the gate-insulating layer GI may be located on the overall surface of the substrate SUB, and may be patterned using the gate layer GTL as a mask. Consequently, the gate-insulating layer GI may be present under only the first capacitor electrode CE1, the gate electrode GE, and the second power line PL2, while the first electrode SE and the second electrode DE of the active layer ACTL that do not overlap the gate electrode GE may be doped with impurities.

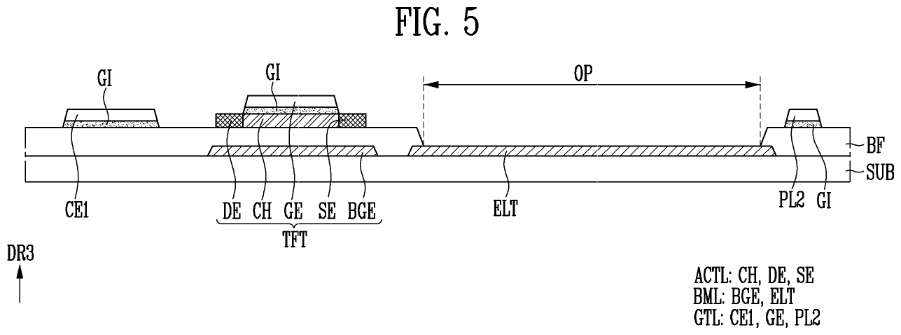

Thereafter, as illustrated in FIG. 5, at least a portion of the buffer layer BF on the pixel electrode ELT may be removed. The pixel electrode ELT may be exposed through the opening OP of the buffer layer BF.

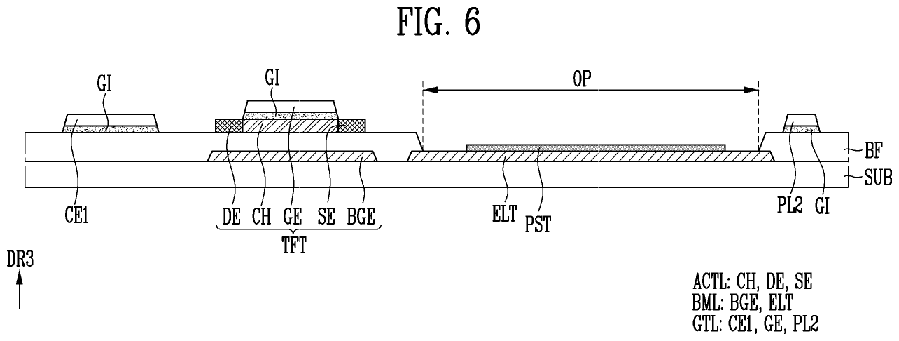

As illustrated in FIG. 6, the adhesive layer PST may be formed on the pixel electrode ELT. In one or more embodiments, the adhesive layer PST may include silver paste.

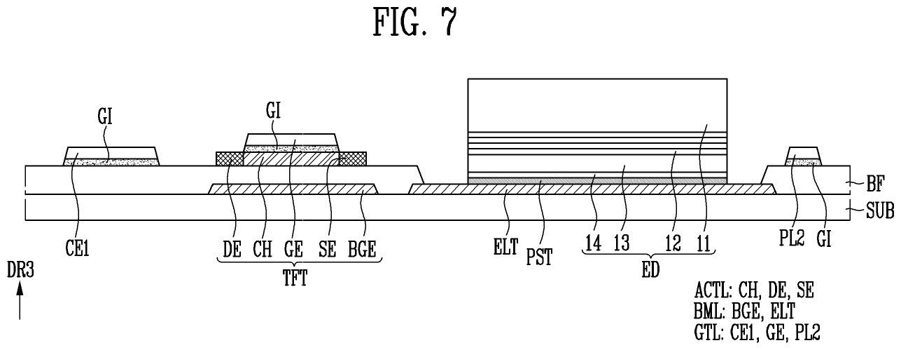

As illustrated in FIG. 7, the light-emitting element ED may be located or mounted on the adhesive layer PST. The element electrode layer 14 (or the first end) of the light-emitting element ED may contact the adhesive layer PST. The element electrode layer 14 of the light-emitting element ED may be electrically connected to the pixel electrode ELT by the adhesive layer PST including silver paste.

For example, the light-emitting element ED may be grown and formed on a semiconductor substrate, such as a silicon wafer. The light-emitting element ED may be transferred from the silicon wafer and directly onto the adhesive layer PST. The light-emitting element ED may be transferred onto the adhesive layer PST either by an electrostatic method using an electrostatic head or by a stamping method using an elastic polymer material, such as PDMS or silicon, for a transfer substrate.

In one or more embodiments, a curing (or heat curing) process may be performed on the adhesive layer PST including silver paste. As described above, curing conditions for the silver paste may be either about 12 hours at about 25° C. or about 30 minutes at about 100° C., and the silver paste may be cured taking into account the curing conditions. The cured silver paste has an adhesive strength ranging from approximately 70 kgf/cm² to approximately 80 kgf/cm², reducing or preventing the likelihood of the light-emitting element ED being removed from the pixel electrode ELT during subsequent processes. In other words, the light-emitting element ED may be fixed (or temporarily fixed) or bonded to the pixel electrode ELT by the cured silver paste. The curing process may be performed before, after, or during the supply of the light-emitting element ED.

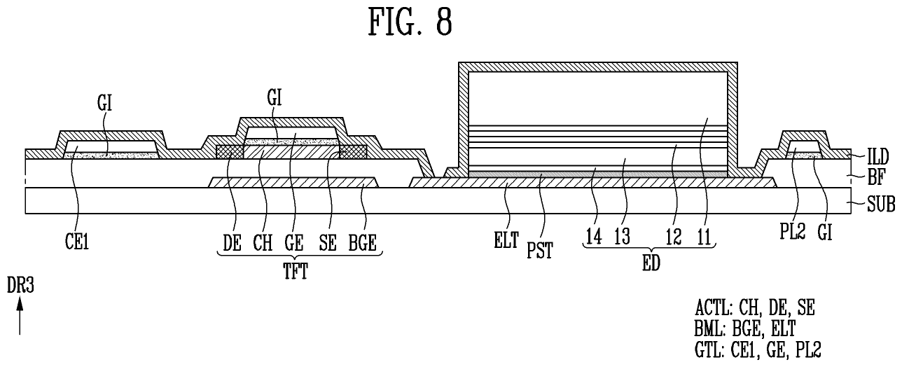

As illustrated in FIG. 8, the interlayer insulating layer ILD may be formed or deposited to cover the gate layer GTL and the light-emitting element ED. The interlayer insulating layer ILD may be formed on the overall surface of the substrate SUB. The interlayer insulating layer ILD may completely fix the light-emitting element ED in place. In other words, the light-emitting element ED may be fixed on the pixel electrode ELT primarily by the adhesive layer PST, and secondarily by the interlayer insulating layer ILD.

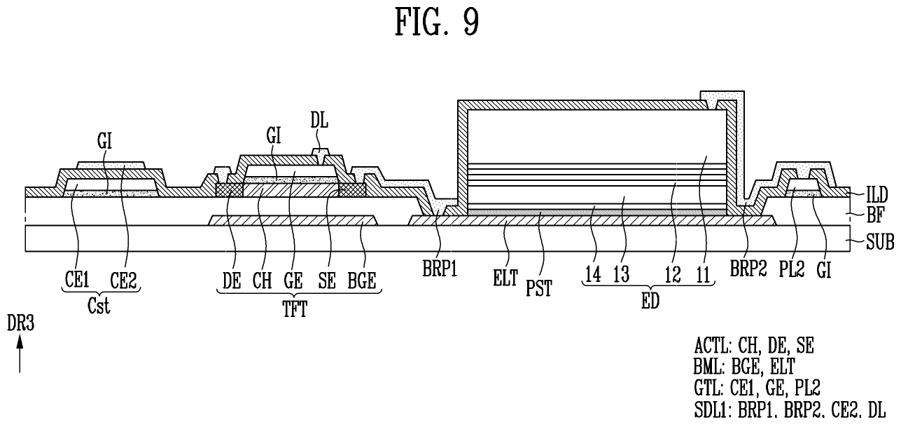

As illustrated in FIG. 9, the first source metal layer SDL1 may be located on the interlayer insulating layer ILD. The first bridge pattern BRP1 may be brought into contact with, or may be connected to, the first electrode SE (or the second electrode DE) of the thin-film transistor TFT through a contact hole passing through the interlayer insulating layer ILD. Furthermore, the first bridge pattern BRP1 may be brought into contact with, or may be connected to, the pixel electrode ELT through a contact hole passing through the interlayer insulating layer ILD. Therefore, the element electrode layer 14 (or the first end) of the light-emitting element ED may be electrically connected to the thin-film transistor TFT through the pixel electrode ELT and the first bridge pattern BRP1.

The second bridge pattern BRP2 may be connected to the first semiconductor layer 11 of the light-emitting element ED through a contact hole passing through the interlayer insulating layer ILD. Furthermore, the second bridge pattern BRP2 may be connected to the second power line PL2 through a contact hole passing through the interlayer insulating layer ILD. Therefore, the first semiconductor layer 11 (or the second end) of the light-emitting element ED may be electrically connected to the second power line PL2 through the second bridge pattern BRP2. The second capacitor electrode CE2 and the first capacitor electrode CE1 may form the capacitor Cst.

Thereafter, the first via layer VIA1, the second source metal layer SDL2, the second via layer VIA2, the third source metal layer SDL3, and the passivation layer PVX may be sequentially formed. As a result, the display device 10 of FIG. 3 may be fabricated. A portion of the interlayer insulating layer ILD that contacts an upper surface (or the second end) of the light-emitting element ED may be exposed from the first and second via layers VIA1 and VIA2 (or organic layers) and the passivation layer PVX (or an inorganic layer).

As described above, the light-emitting element ED may be primarily fixed (or temporarily fixed) to the pixel electrode ELT by the adhesive layer PST, and secondarily fixed to the pixel electrode ELT by the interlayer insulating layer ILD. The light-emitting element ED may be fixed or coupled to the pixel electrode ELT through only a low-temperature process without the need for a high-temperature and/or press process.

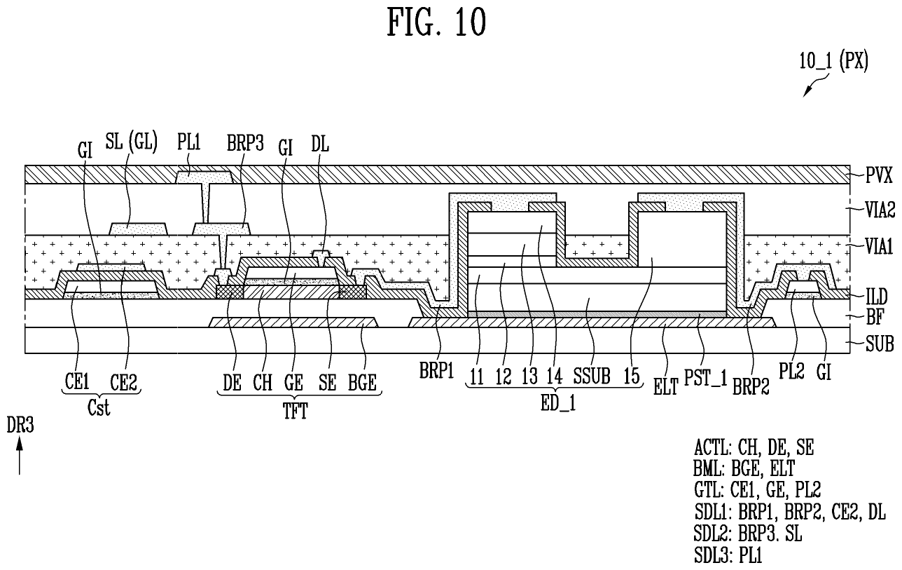

FIG. 10 is a sectional view illustrating one or more embodiments of the display device of FIG. 1.

Referring to FIGS. 1, 3, and 10, the configurations of a display device 10_1 of FIG. 10, other than a light-emitting element ED_1, may be substantially identical or similar to that of the display device 10 of FIG. 3. Therefore, repetitive explanation thereof will be omitted.

The light-emitting element ED_1 may include a base substrate SSUB, a first semiconductor layer 11, an emission layer 12, a second semiconductor layer 13, an element electrode layer 14 (or a first contact electrode), and a contact electrode layer 15 (or a second contact electrode). The light-emitting element ED_1 may be a flip-chip type micro LED, and may have a mesa structure.

The base substrate SSUB may be a sapphire substrate, but is not limited thereto.

The first semiconductor layer 11, the emission layer 12, the second semiconductor layer 13, and the element electrode layer 14 may be sequentially located on the base substrate SSUB. A portion of the first semiconductor layer 11 may be exposed from the emission layer 12. The contact electrode layer 15 may be located on the portion of the first semiconductor layer 11. The contact electrode layer 15 may include the same material as that of the element electrode layer 14.

The interlayer insulating layer ILD may cover the light-emitting element ED_1.

The first bridge pattern BRP1 may be brought into contact with, or may be connected to, the element electrode layer 14 of the light-emitting element ED through a contact hole passing through the interlayer insulating layer ILD. The first bridge pattern BRP1 may be directly connected to the element electrode layer 14 of the light-emitting element ED without the pixel electrode ELT.

The second bridge pattern BRP2 may be brought into contact with, or may be connected to, the contact electrode layer 15 of the light-emitting element ED through a contact hole passing through the interlayer insulating layer ILD. The first bridge pattern BRP1 may be directly connected to the contact electrode layer 15 of the light-emitting element ED without the pixel electrode ELT.

In one or more embodiments, an adhesive layer PST_1 may include silver paste. However, because the base substrate SSUB is an insulator, the light-emitting element ED_1 (e.g., a bottom surface thereof) may be electrically separated from the pixel electrode ELT. The pixel electrode ELT may electrically float. In one or more embodiments, the pixel electrode ELT may not be necessary, and may be omitted.

In one or more embodiments, the pixel electrode ELT may function as a heat dissipation plate. For example, heat generated from the light-emitting element ED_1 may be transferred to the pixel electrode ELT through the silver paste having relatively high heat conductivity. The heat may be discharged to the outside through the pixel electrode ELT and a lower portion of the substrate SUB. In the case where the pixel electrode ELT is formed on the overall surface of the substrate SUB other than the bottom gate electrode BGE, the use of the pixel electrode ELT having a planar shape may enhance the heat dissipation effect.

In one or more embodiments, the adhesive layer PST_1 may include insulating material, such as photoresist. The photoresist may also have a similar level of adhesive strength as silver paste, and may fix the light-emitting element ED_1 to the pixel electrode ELT. Because there is no need for electrical connection between the light-emitting element ED_1 and the pixel electrode ELT, the adhesive layer PST_1 may omit conductive particles. In this case as well, the pixel electrode ELT may function as a heat dissipation plate.

As described above, the pixel electrode ELT is electrically separated from the light-emitting element ED_1, and may function as a heat dissipation plate designed to dissipate heat generated from the light-emitting element ED_1 to the outside.

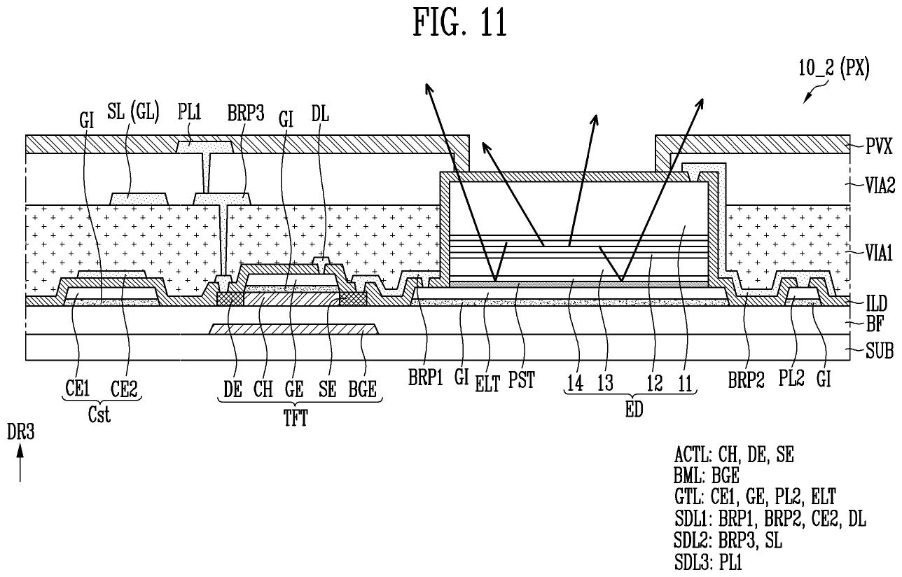

FIG. 11 is a sectional view illustrating one or more embodiments of the display device of FIG. 1.

Referring to FIGS. 1, 3, and 11, the configurations of a display device 10_2 of FIG. 11, other than the placement position of the pixel electrode ELT (and the corresponding placement position of the light-emitting element ED), may be substantially identical or similar to that of the display device 10 of FIG. 3. Therefore, repetitive explanation thereof will be omitted.

In embodiments, the pixel electrode ELT may be located in the same layer as one of the electrodes of the thin-film transistor TFT.

In one or more embodiments, the pixel electrode ELT may be located on the buffer layer BF. The pixel electrode ELT may be positioned in the same layer as the first electrode SE (or the second electrode DE) of the thin-film transistor TFT included in the active layer ACTL.

In one or more embodiments, the pixel electrode ELT may be included in the gate layer GTL. In other words, the pixel electrode ELT may be concurrently or substantially simultaneously formed with the gate electrode GE of the thin-film transistor TFT included in the gate layer GTL through the same process. In this case, the gate layer GTL including the pixel electrode ELT may include conductive materials having high reflectance, such as silver (Ag), copper (Cu), and/or aluminum (Al).

The adhesive layer PST may be located on the pixel electrode ELT. The light-emitting element ED may be located on the adhesive layer PST. The interlayer insulating layer ILD may cover the light-emitting element ED.

As described above, the pixel electrode ELT may be located in the same layer as one of the electrodes of the thin-film transistor TFT. The pixel electrode ELT may be located in the same layer as the gate electrode GE of the thin-film transistor TFT.

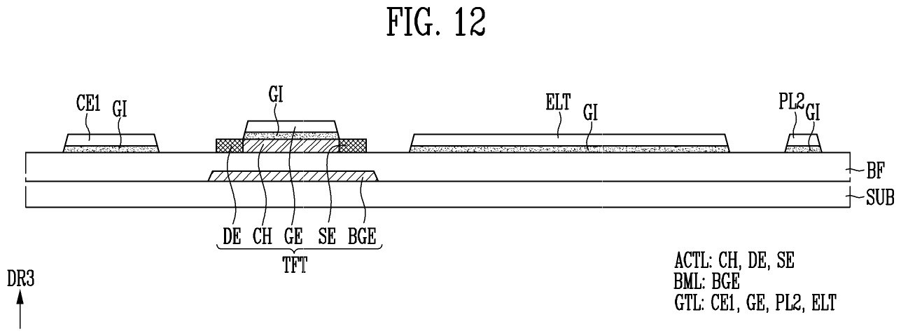

FIGS. 12 to 16 are sectional views illustrating a method of fabricating the display device of FIG. 11.

Referring to FIGS. 11 to 16, the thin-film transistor TFT and the pixel electrode ELT may be formed on the substrate SUB. In the following description, explanations pertaining to content that overlaps the embodiments in FIGS. 4 to 9 will be omitted.

As illustrated in FIG. 12, the bottom electrode layer BML that includes the bottom gate electrode BGE may be formed on the substrate SUB. The buffer layer BF may be formed to cover the bottom electrode layer BML. The active layer ACTL may be located on the buffer layer BF to overlap the bottom gate electrode BGE. The gate-insulating layer GI may be located on the active layer ACTL. The gate layer GTL may be located on the gate-insulating layer GI. The gate layer GTL may include the pixel electrode ELT. The pixel electrode ELT may include conductive material having relatively high reflectance.

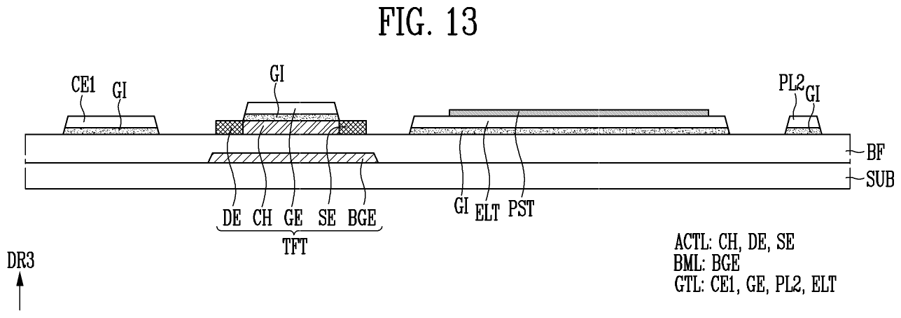

As illustrated in FIG. 13, the adhesive layer PST may be formed on the pixel electrode ELT. In one or more embodiments, the adhesive layer PST may include silver paste.

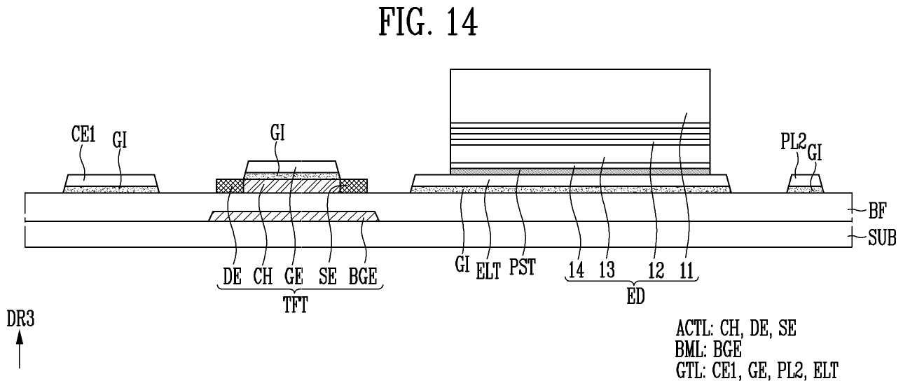

As illustrated in FIG. 14, the light-emitting element ED may be located or mounted on the adhesive layer PST.

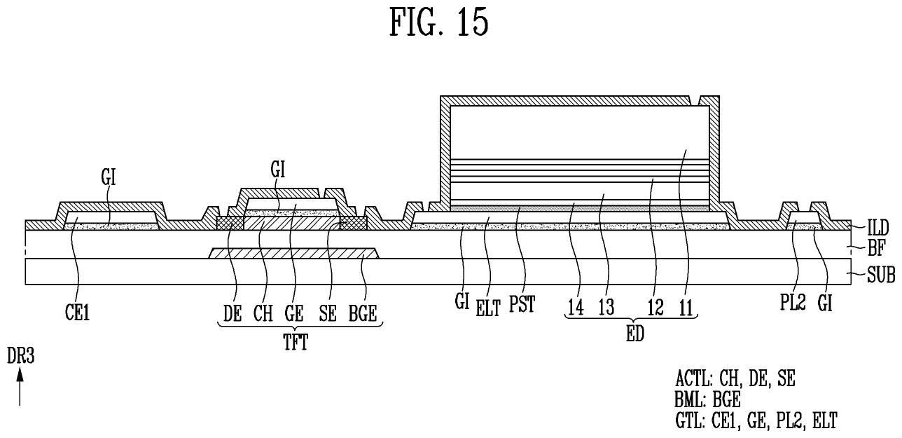

Thereafter, as illustrated in FIG. 15, the interlayer insulating layer ILD may be formed or deposited to cover the gate layer GTL and the light-emitting element ED. The interlayer insulating layer ILD may be formed on the overall surface of the substrate SUB. The interlayer insulating layer ILD may completely fix the light-emitting element ED in place. In other words, the light-emitting element ED may be fixed on the pixel electrode ELT primarily by the adhesive layer PST, and secondarily by the interlayer insulating layer ILD.

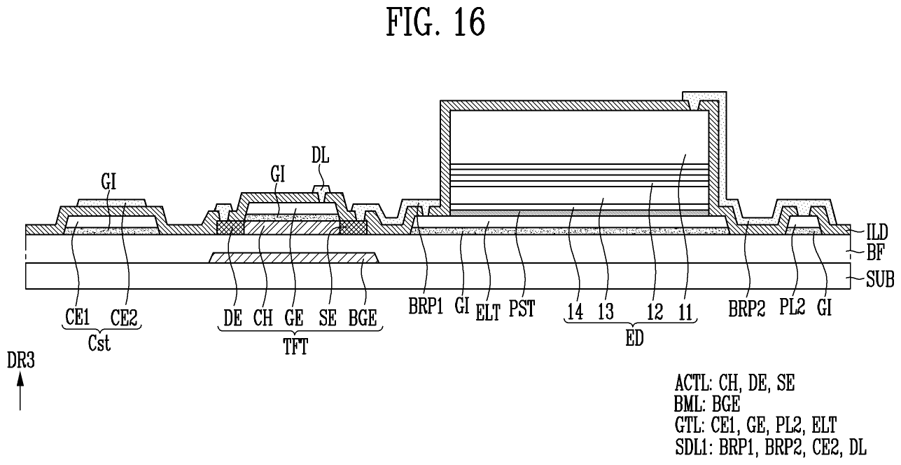

As illustrated in FIG. 16, the first source metal layer SDL1 may be located on the interlayer insulating layer ILD.

Thereafter, the first via layer VIA1, the second source metal layer SDL2, the second via layer VIA2, the third source metal layer SDL3, and the passivation layer PVX may be sequentially formed. As a result, the display device 10_2 of FIG. 11 may be fabricated.

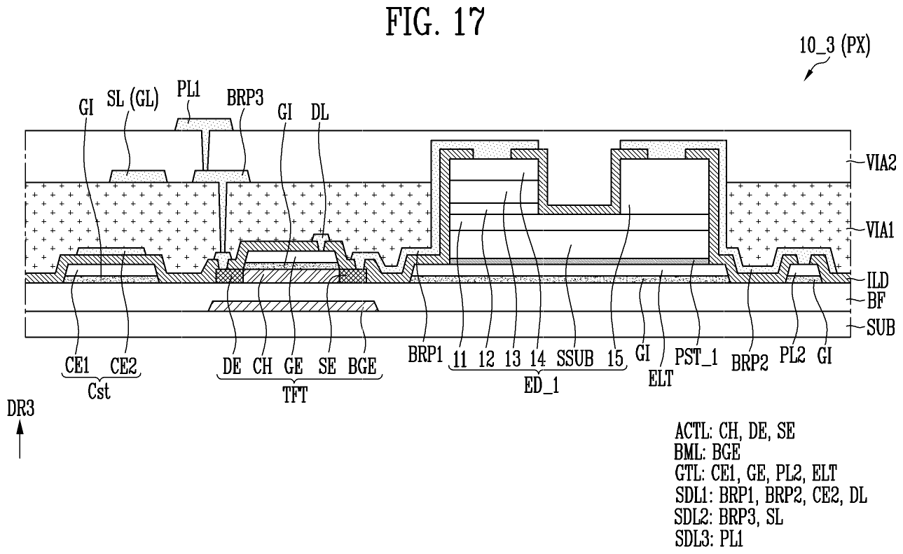

FIG. 17 is a sectional view illustrating one or more embodiments of the display device of FIG. 1.

Referring to FIGS. 1, 10, and 17, the configurations of a display device 10_3 of FIG. 17, other than the disposition of the pixel electrode ELT (and the corresponding disposition of a light-emitting element ED_1), may be substantially identical or similar to that of the display device 10 of FIG. 3. Therefore, repetitive explanation thereof will be omitted.

Furthermore, because the disposition of the pixel electrode ELT of FIG. 17 and the corresponding disposition of the light-emitting element ED_1 have been described with reference to FIG. 11, further explanation thereof will be omitted.

The pixel electrode ELT may be included in the gate layer GTL and electrically separated from the light-emitting element ED_1, and may function as a heat dissipation plate designed to dissipate heat generated from the light-emitting element ED_1 to the outside.

In a display device in accordance with embodiments of the present disclosure, a pixel electrode is located in the same layer as one of electrodes of a transistor. A light-emitting element may be temporarily fixed (or primarily fixed) to pixel electrode by an adhesive layer. An insulating layer (or an interlayer insulating layer) may directly cover the light-emitting element, thus completely (or secondarily) fixing the light-emitting element in place. The light-emitting element may be fixed in place by the adhesive layer and the insulating layer through only a low-temperature process without the need for a high-temperature process and/or a press process. Therefore, damage to components in the display device due to high-temperature processes can be reduced or prevented from occurring, whereby the yield of the display device may be improved.

Furthermore, the insulating layer may directly cover an outer circumferential surface (or a side surface) of the light-emitting element, thus reducing or minimizing surface defects of the light-emitting element. Therefore, there is no need to form a separate insulating layer (e.g., an insulating layer for reducing or minimizing surface defects) on the light-emitting element during a process of fabricating the light-emitting element. Therefore, the production cost of the light-emitting element and the display device including the light-emitting element may be reduced.

The effects of the present disclosure are not limited by the foregoing, and other various effects are anticipated herein.

While the spirit and scope of the present disclosure are described by detailed embodiments, it should be noted that the above-described embodiments are merely descriptive and should not be considered limiting. It should be understood by those skilled in the art that various changes, substitutions, and alternations may be made herein without departing from the scope of the disclosure as defined by the following claims, with functional equivalents thereof to be included therein.

1 what is claimed is:

1. A method of fabricating a display device, the method comprising:
forming a transistor above a substrate, and a pixel electrode at a same layer as one of electrodes of the transistor;
forming an adhesive layer on the pixel electrode;
placing a light-emitting element on the adhesive layer;
forming an insulting layer to cover the transistor, the pixel electrode, and the light-emitting element; and
forming a first bridge pattern electrically connecting the transistor to a first end of the light-emitting element, and a second bridge pattern electrically connected to a second end of the light-emitting element,
wherein the light-emitting element is primarily fixed by the adhesive layer, and
wherein the light-emitting element is secondarily fixed by the insulating layer.

2. The method according to claim 1, wherein the light-emitting element comprises a first semiconductor layer, an emission layer, and a second semiconductor layer that are sequentially stacked from the second end to the first end, and
wherein an outer circumferential surface of each of the first semiconductor layer, the emission layer, and the second semiconductor layer is covered with the insulating layer.

3. The method according to claim 2, wherein the insulating layer comprises inorganic material.

4. The method according to claim 1, wherein the first end of the light-emitting element contacts the adhesive layer,
wherein the first bridge pattern contacts the pixel electrode, and
wherein the first end of the light-emitting element is electrically connected to the pixel electrode by the adhesive layer.

5. The method according to claim 4, wherein the adhesive layer comprises silver paste,
wherein forming the adhesive layer comprises heat-curing the silver paste, and
wherein the light-emitting element is fixed to the pixel electrode by the cured silver paste.

6. The method according to claim 5, wherein the pixel electrode comprises reflective metal.

7. The method according to claim 1, further comprising forming an organic layer and an inorganic layer on the insulating layer,
wherein a portion of the insulating layer in contact with the second end of the light-emitting element is exposed from the organic layer and the inorganic layer.

8. The method according to claim 1, wherein the transistor comprises a gate electrode above a semiconductor pattern, and a back gate electrode beneath the semiconductor pattern and overlapping the gate electrode, and
wherein the pixel electrode is at a same layer as the back gate electrode.

9. The method according to claim 1, wherein the transistor comprises a gate electrode above a semiconductor pattern, and
wherein the pixel electrode is at a same layer as the gate electrode.

10. The method according to claim 1, wherein the adhesive layer comprises photoresist, and
wherein the pixel electrode is electrically separated from a bottom surface of the light-emitting element and the transistor.

11. A display device comprising:
a transistor above a substrate;
a pixel electrode at a same layer as one of electrodes of the transistor;
an adhesive layer above the pixel electrode;
a light-emitting element above the adhesive layer, and comprising a first semiconductor layer, an emission layer, and a second semiconductor layer that are sequentially stacked from a second end to a first end;
an insulting layer covering the transistor, the pixel electrode, and the light-emitting element, and covering an outer circumferential surface of the first semiconductor layer, the emission layer, and the second semiconductor layer;
a first bridge pattern above the insulating layer, and electrically connecting the transistor to the first end of the light-emitting element; and
a second bridge pattern above the insulating layer, and electrically connected to the second end of the light-emitting element.

12. The display device according to claim 11, wherein the first bridge pattern contacts the pixel electrode, and
wherein the first end of the light-emitting element contacts the adhesive layer to be electrically connected to the pixel electrode.

13. The display device according to claim 12, wherein the adhesive layer comprises silver paste, and
wherein the light-emitting element is fixed to the pixel electrode by the silver paste being cured.

14. The display device according to claim 13, wherein the pixel electrode comprises reflective metal.

15. The display device according to claim 11, further comprising an organic layer and an inorganic layer sequentially on the insulating layer,
wherein a portion of the insulating layer in contact with the second end of the light-emitting element is exposed from the organic layer and the inorganic layer.

16. The display device according to claim 11, wherein the transistor comprises a gate electrode above a semiconductor pattern, and a back gate electrode beneath the semiconductor pattern and overlapping the gate electrode, and
wherein the pixel electrode is at a same layer as the back gate electrode.

17. The display device according to claim 12, wherein the transistor comprises a gate electrode above a semiconductor pattern, and
wherein the pixel electrode is at a same layer as the gate electrode.

18. The display device according to claim 11, wherein the adhesive layer comprises photoresist.

19. The display device according to claim 18, wherein the pixel electrode is electrically separated from a bottom surface of the light-emitting element.

20. The display device according to claim 11, wherein the light-emitting element comprises a flip-chip-type micro light-emitting diode.
